(19) United States
(12) Patent Application Publication
(10) Pub. No.: US 2026/0227807 A1
(43) Pub. Date: Aug. 6, 2026

(54) EXCISING FLUID LEAKAGE FROM THE CHASSIS OF AN INFORMATION HANDLING SYSTEM

(71) Applicant: DELL PRODUCTS L.P., Round Rock, TX (US)

(72) Inventors: Patrick Illingworth, Austin, TX (US); Russell Smith, Taylor, TX (US); Lawrence Kyle, Austin, TX (US)

(21) Appl. No.: 19/044,769

(22) Filed: Feb. 4, 2025

(51) Int. Cl. G05D 9/12

(52) U.S. Cl. CPC G05D 9/12

(57) ABSTRACT

A fluid removal subsystem to excise leaked coolant from an information handling system includes an electric self-priming pump. The electric self-priming pump is encased in a housing sized to fit entirely within a chassis of the information handling system. An intake port and an outtake port are formed in the housing. Intake tubing may be connected with the intake port, and outtake tubing connected with the outtake port. The electric self-priming pump is configured to draw fluid within the chassis into the intake tubing and discharge the fluid through the outtake tubing to thereby remove at least a portion of the fluid from the chassis.

### FIELD OF THE DISCLOSURE

The present disclosure generally relates to information handling systems, and more particularly relates to removing leaked coolant from the chassis of a liquid-cooled information handling system.

### BACKGROUND

As the value and use of information continues to increase, individuals and businesses seek additional ways to process and store information. One option is an information handling system. An information handling system generally processes, compiles, stores, or communicates information or data for business, personal, or other purposes. Technology and information handling needs and requirements can vary between different applications. Thus, information handling systems can also vary regarding what information is handled, how the information is handled, how much information is processed, stored, or communicated, and how quickly and efficiently the information can be processed, stored, or communicated. The variations in information handling systems allow information handling systems to be general or configured for a specific user or specific use such as financial transaction processing, airline reservations, enterprise data storage, or global communications. In addition, information handling systems can include a variety of hardware and software resources that can be configured to process, store, and communicate information and can include one or more computer systems, graphics interface systems, data storage systems, networking systems, and mobile communication systems. Information handling systems can also implement various virtualized architectures. Data and voice communications among information handling systems may be via networks that are wired, wireless, or some combination.

### SUMMARY

A fluid removal subsystem to excise leaked coolant from an information handling system includes an electric self-priming pump. The electric self-priming pump is encased in a housing sized to fit entirely within a chassis of the information handling system. An intake port and an outtake port are formed in the housing. Intake tubing may be connected with the intake port, and outtake tubing connected with the outtake port. The electric self-priming pump is configured to draw fluid within the chassis into the intake tubing and discharge the fluid through the outtake tubing to thereby remove at least a portion of the fluid from the chassis.

### BRIEF DESCRIPTION OF THE DRAWINGS

It will be appreciated that for simplicity and clarity of illustration, elements illustrated in the Figures are not necessarily drawn to scale. For example, the dimensions of some elements may be exaggerated relative to other elements. Embodiments incorporating teachings of the present disclosure are shown and described with respect to the drawings herein, in which:

FIG. 1 is a perspective view of a fluid removal subsystem for removing fluid from a liquid-cooled information handling system according to an embodiment of the present disclosure;

FIG. 2 is a perspective view of a liquid-cooled information handling system including a fluid removal subsystem according to an embodiment of the present disclosure;

FIG. 3 is a cross-sectional view of a distal end of outtake tubing of a fluid removal subsystem according to an embodiment of the present disclosure;

FIG. 4 is a flow diagram of a method for removing fluid from a liquid-cooled information handling system according to an embodiment of the present disclosure; and

FIG. 5 is a block diagram of a general information handling system according to an embodiment of the present disclosure.

The use of the same reference symbols in different drawings indicates similar or identical items.

### DETAILED DESCRIPTION OF THE DRAWINGS

The following description in combination with the Figures is provided to assist in understanding the teachings disclosed herein. The description is focused on specific implementations and embodiments of the teachings and is provided to assist in describing the teachings. This focus should not be interpreted as a limitation on the scope or applicability of the teachings.

For purposes of this disclosure, an information handling system is one that includes a liquid cooling apparatus or subassembly. Such an information handling system can include any instrumentality or aggregate of instrumentalities operable to compute, calculate, determine, classify, process, transmit, receive, retrieve, originate, switch, store, display, communicate, manifest, detect, record, reproduce, handle, or utilize any form of information, intelligence, or data for business, scientific, control, or other purposes. For example, such an information handling system may be a computer, server such as a blade server or rack-mounted server, a network storage device, or any other such device and which may vary in size, shape, performance, functionality, and/or price. The information handling system may include random access memory (RAM), one or more processing resources such as a central processing unit (CPU), graphics processing unit (GPU), hardware and/or software control logic, as well as ROM and/or other types of nonvolatile memory. Additional components of the information handling system may include one or more disk drives, one or more network ports for communicating with external devices as well as various input and output (I/O) devices, such as a keyboard, a mouse, touchscreen and/or a video display. The information handling system may also include one or more buses operable to transmit communications between the various hardware components.

As the processing power of information handling systems continues to increase, the use of liquid cooling is expected to become more common owing to certain advantages that liquid cooling offers over other types of cooling. A liquid cooling apparatus or subassembly typically includes a pump, radiator, reservoir, and cold plates connected via tubing that circulates coolant within the chassis of an information handling system. The coolant circulates in a closed loop within the chassis, transferring heat away from critical components of the information handling system.

Notwithstanding the advantages of liquid cooling, there is the possibility that one or more components of the liquid cooling apparatus or subassembly may develop leaks over time due to vibration, thermal cycles, aging, misalignment of heat exchangers or cold blocks, or the like. Any leak that exposes the components of the information handling system to liquid can cause corrosion or damage to the circuitry within the system's housing. In certain arrangements, a coolant leak occurring in one information handling system also may damage one or more nearby information handling systems if the systems are sufficiently close to one another. For example, a leak may occur in one of multiple servers stacked on a vertical rack (an increasingly common configuration). As leaked coolant builds up in one information handling system on the vertical rack, there is an increasing risk that the leaked coolant may overflow onto other information handling systems lower on the vertical rack. If the leak is not detected early enough, there is a cascading effect of leaked coolant that has the potential to damage not only the information handling system in which the leak occurred but one or more additional information handlings systems below.

The risk that a coolant leak in one information handling system may spill over onto another information handling system is especially troublesome given that the number of vertical racks is likely to increase as datacenters expand to deal with high-density data processing tasks such as cloud computing, artificial intelligence, and machine learning. Given the risk, it is important to not only detect coolant leaks rapidly, but also to mitigate the risk of a cascade of damage when owing to a leak in one information handling system fluid spills over to one or more systems positioned lower on a vertical rack.

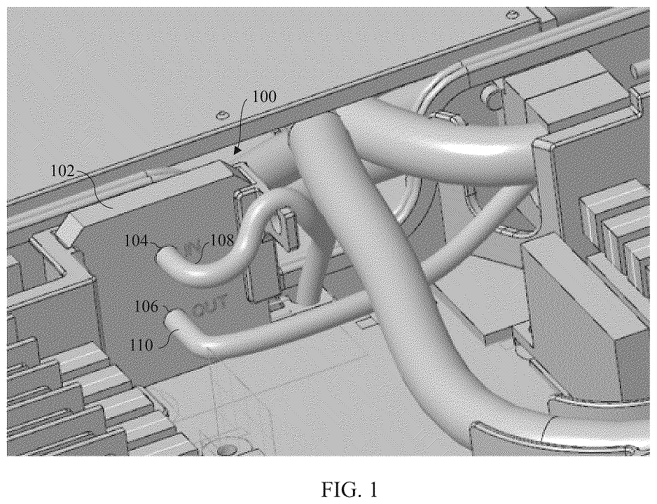

FIG. 1 is a perspective view of an example fluid removal subsystem 100 for removing fluid from a liquid-cooled information handling system according to an embodiment of the present disclosure. Illustratively, fluid removal subsystem 100 is positioned within the interior of a chassis of the liquid-cooled information handling system. Fluid removal subsystem 100 includes an electric self-priming pump enclosed within housing 102. Intake port 104 and outtake port 106 are formed in the surface of housing 102. Intake tubing 108 is connected to the electric self-priming pump via intake port 104. Similarly, outtake tubing 110 is connected to the self-priming pump via outtake port 106. In various embodiments, the size of housing 102 may vary to accommodate the specific dimensions of the chassis of a particular liquid-cooled information handling system in which fluid removal subsystem 100 is positioned. Housing 102, in various embodiments, thus may be sized to fit entirely within the chassis of the liquid-cooled information handling system.

In certain embodiments, fluid removal subsystem 100 is implemented using a piezoelectric self-priming pump as the electric self-priming pump enclosed within housing 102. Fluid movement with the piezoelectric self-priming pump is induced by pressure differences generated by expansions and contractions of a diaphragm, which expands and contracts in response to voltage-induced deformation of a piezoelectric element. An average fluid flow rate of approximately 15 milliliters (ml) per minute (min) may be achieved, for example, with a piezoelectric self-priming pump whose dimensions are approximately 27.5 millimeters (mm) by approximately 5.3 mm. Implemented with the piezoelectric self-priming pump within housing 102, fluid removal subsystem 100 may be sufficiently sized to fit within relatively narrow spaces of the interior of the chassis of a liquid-cooled information handling system.

In other embodiments, fluid removal subsystem 100 may be implemented using other types of electric self-priming pumps within housing 102. For example, fluid removal subsystem 100 may be implemented using a self-priming brushless direct current (DC) centrifugal pump within housing 102. Fluid movement with the self-priming brushless DC centrifugal pump is caused by rotation of an impeller connected with a shaft that is rotated by a brushless DC motor. Rotation of the impeller creates a vacuum to prime the pump, after which the self-priming brushless DC centrifugal pump operates as a conventional centrifugal pump to generate fluid movement. Fluid removal subsystem 100 may be sufficiently sized to fit within the interior of the chassis of liquid-cooled information handling systems using the self-priming brushless DC centrifugal pump or other types of electric self-priming pumps.

Operatively, in each of the various embodiments, the electric self-priming pump of fluid removal subsystem 100 draws fluid from the interior of the chassis of a liquid-cooled information handling system, drawing the fluid into intake tubing 108. The fluid is then discharged by the electric self-priming pump through outtake tubing 110.

In certain embodiments, fluid removal subsystem 100 includes a fluid sensor operatively coupled with the electric self-priming pump positioned within housing 102. Operatively, the fluid sensor initiates operation of the electric self-priming pump in response to the fluid sensor's detecting the presence of fluid within the chassis of the information handling system. In some embodiments, in response to detecting fluid within the chassis of the information handling system, the fluid sensor emits a signal that throws a switch (not shown) that is integrated with the electric self-priming pump. Self-priming pumps typically operate in two modes: the initial priming mode and the subsequent pumping mode. Activating the switch may initiate the priming mode, which once completed enables the electric self-priming pump to begin drawing fluid into intake tubing 108 for discharging the fluid via outtake tubing 110. In some embodiments, the fluid sensor may be a capacitive sensor formed with a pair of diodes and that detects the presence of fluid in response to a change in capacitance between the fluid due to the presence of a fluid, for example. In other embodiments, the fluid sensor may be an electro-optic sensor that detects the presence of the fluid in response light refraction induced by the fluid, for example. In still other embodiments, different types of fluid sensors may be used by fluid removal subsystem 100.

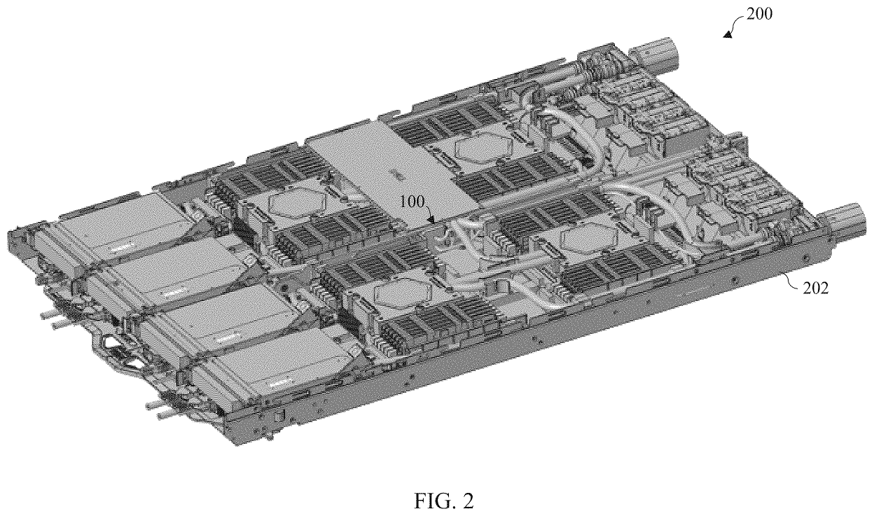

Fluid removal subsystem 100, in various embodiments, may be positioned to capture flows of fluid that naturally occur within the chassis due, for example, to the slope of the chassis floor or other structure-related factors. FIG. 2 illustrates the positioning of fluid removal subsystem 100 within liquid-cooled information handling system 200 according to one embodiment of the present disclosure. Illustratively, fluid removal subsystem is positioned substantially in the center of chassis base 202 of liquid-cooled information handling system 200. The center portion of chassis base 202 may be relatively lower than the outward regions nearer the edges of the chassis base due to inherent sag in the approximate center of the chassis floor, causing a downward slope toward the center. Coolant leaked from a liquid cooling apparatus thus may result in naturally occurring sag flows as the coolant flows along the downward slope toward the center. The positioning of fluid removal subsystem 100 substantially centered in chassis base 202 may enable fluid removal subsystem 100 to capture the naturally occurring sag flows. Depending on the structure of a chassis base, fluid removal subsystem 100 may be positioned at other locations within the chassis to capture naturally occurring flows of fluid leaked from a liquid cooling apparatus or subassembly.

Fluid removal subsystem 100 may be positioned so that the distal end of intake tubing 108 does not extend beyond a certain distance from the electric self-priming pump but is positioned to most likely capture such naturally occurring fluid flows. Accordingly, intake tubing 108 may be positioned within the chassis of an information handling system to capture a flow of fluid naturally occurring within the chassis owing to the slope of the chassis floor, for example.

In certain embodiments, fluid removal subsystem 100 may be positioned to capture fluid flowing in a direction dictated by different types of fluid flow controls of the information handling system. Fluid removal subsystem 100 may be positioned such that intake tubing 108 is positioned within the chassis to capture fluid flows within one or more fluid channels of the chassis. The channels may be naturally occurring owing to design features of a particular chassis or may be predetermined by designers to ensure or to make more likely that fluid flows that may arise to a leakage from the liquid cooling apparatus or subassembly flow in a desired direction.

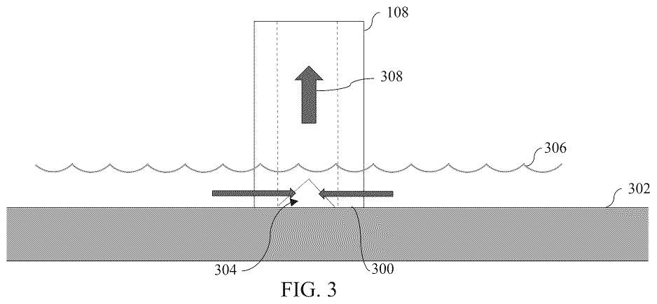

FIG. 3 illustrates an example construct of intake tubing 108. Illustratively, distal end 300 of intake tubing 108 is substantially flush with floor 302 of an information handling system chassis. Notch 304 is formed in a portion of distal end 300 of intake tubing 108. Notch 304 permits fluid 306 to flow into intake tubing 108 while the tubing is flush with floor 302 of the chassis. Upward flow 308 of the fluid is induced by the suction created by the electric self-priming pump in housing 102. Illustratively, notch 304 is V-shaped. In other embodiments, however, notch 304 may take different shapes that permit fluid to flow into intake tubing 108.

Fluid removal system 100, by removing all, substantially all, or at least a portion of fluid from the chassis of an information handling system, may prevent a fluid buildup that could overflow from the chassis. Such overflow can damage one or more other information handling systems if the information handling systems are arrayed on a vertical rack, for example, within a datacenter. Many top covers of information handling systems, as currently designed, are not completely sealed to prevent fluids from entering through the lever assembly and seams between a top cover and chassis base. To prevent a fluid overflow that might damage information handling systems lower on a vertical server rack, fluid removal subsystem 100 may be placed in an information handling system that is above one or more others on the rack. In certain embodiments, outtake tubing 110 may be configured to deliver fluid withdrawn by the electric self-priming pump from the information handling system chassis to an external drainage system of the rack assembly.

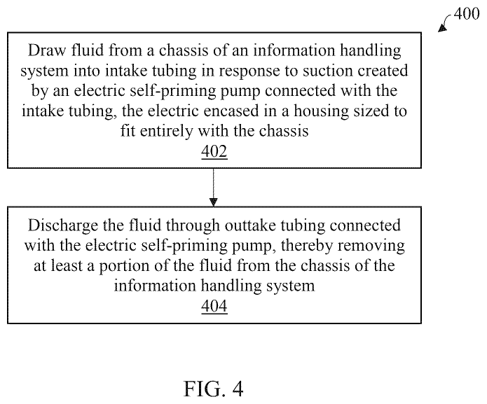

FIG. 4 is a flow diagram of example method 400 for excising fluid within a liquid-cooled information handling system. It will be readily appreciated that not every method step set forth in this flow diagram is always necessary, and that certain steps of the methods may be combined, performed simultaneously, in a different order, or omitted without varying from the scope of the disclosure. Method 400 may be performed by a fluid removal subsystem having features of fluid removal subsystem 100 described with reference to FIGS. 1-3.

At block 402, the fluid removal subsystem draws fluid from the chassis of an information handling system. The fluid is drawn into intake tubing in response to suction created by an electric self-priming pump connected with the intake tubing. The electric self-priming pump is encased in a housing sized to fit entirely within chassis of the information handling system.

At block 404, the electric self-priming pump discharges the fluid through outtake tubing connected with the electric self-priming pump. The discharge removes at least a portion of the fluid from the chassis of the information handling system.

Method 400, in certain embodiments, may include initiating operation of the electric self-priming pump in response to detecting the fluid by a fluid sensor communicatively coupled with the electric self-priming pump. In some embodiments, the fluid sensor may be a capacitive sensor. In other embodiments, the fluid sensor may be an electro-optic sensor. The fluid sensor, in certain embodiments, may cause the electric self-priming pump to begin operating in the priming mode. Having completed the priming, the electric self-priming pump can begin drawing fluid into intake tubing for discharging the fluid via outtake tubing.

In certain embodiments, method 400 may be performed by the fluid removal system with a distal end of the intake tubing fitted against a floor of the chassis. A notch may be formed in the distal end of the intake tubing to permit the fluid to be drawn into the intake tubing in response to suction created by the electric self-priming pump. The intake tubing may be positioned within the chassis to capture a flow of fluid naturally occurring within the chassis owing to a slope of a floor of the chassis. In other arrangements, the intake tubing may be positioned to capture fluid flows within one or more fluid channels of the chassis. The outtake tubing may be configured to deliver fluid withdrawn by the electric self-priming pump from the chassis to an external drainage system of a rack assembly.

In certain embodiments, method 400 may be performed by a fluid removal system in which the electric self-priming pump is a piezoelectric self-priming pump. In other embodiments, the electric self-priming pump may be a brushless DC centrifugal pump or other type of electric self-priming pump.

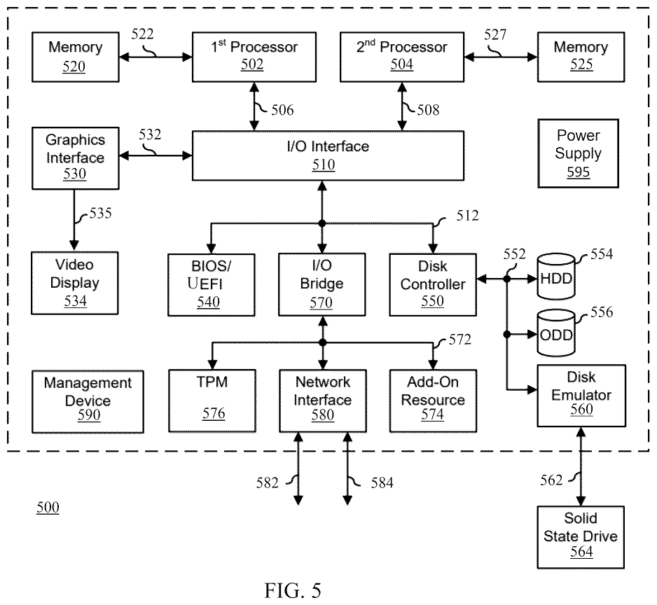

FIG. 5 shows a generalized embodiment of an information handling system 500 according to an embodiment of the present disclosure. Information handling system 500 may be substantially similar to one whose components are housed within a chassis such as that described with reference to FIGS. 1-3. For purpose of this disclosure an information handling system can include any instrumentality or aggregate of instrumentalities operable to compute, classify, process, transmit, receive, retrieve, originate, switch, store, display, manifest, detect, record, reproduce, handle, or utilize any form of information, intelligence, or data for business, scientific, control, entertainment, or other purposes. For example, information handling system 500 can be a computer, a network server, a network storage device, a switch router or other network communication device, or any other suitable device sufficiently sized to accommodate a liquid cooling apparatus or system and which may vary in size, shape, performance, functionality, and price. Further, information handling system 500 can include processing resources for executing machine-executable code, such as a central processing unit (CPU), a programmable logic array (PLA), an embedded device such as a System-on-a-Chip (SoC), or other control logic hardware. Information handling system 500 can also include one or more computer-readable mediums for storing machine-executable code, such as software or data. Additional components of information handling system 500 can include one or more storage devices that can store machine-executable code, one or more communications ports for communicating with external devices, and various input and output (I/O) devices, such as a keyboard, a mouse, and a video display. Information handling system 500 can also include one or more buses operable to transmit information between the various hardware components.

Information handling system 500 can include devices or modules that embody one or more of the devices or modules described below and operates to perform one or more of the methods described below. Information handling system 500 includes a processors 502 and 504, an input/output (I/O) interface 510, memories 520 and 525, a graphics interface 530, a basic input and output system/universal extensible firmware interface (BIOS/UEFI) module 540, a disk controller 550, a hard disk drive (HDD) 554, an optical disk drive (ODD) 556, a disk emulator 560 connected to an external solid state drive (SSD) 564, an I/O bridge 570, one or more add-on resources 574, a trusted platform module (TPM) 576, a network interface 580, a management device 590, and a power supply 595. Processors 502 and 504, I/O interface 510, memory 520, graphics interface 530, BIOS/UEFI module 540, disk controller 550, HDD 554, ODD 556, disk emulator 560, SSD 564, I/O bridge 570, add-on resources 574, TPM 576, and network interface 580 operate together to provide a host environment of information handling system 500 that operates to provide the data processing functionality of the information handling system. The host environment operates to execute machine-executable code, including platform BIOS/UEFI code, device firmware, operating system code, applications, programs, and the like, to perform the data processing tasks associated with information handling system 500.

In the host environment, processor 502 is connected to I/O interface 510 via processor interface 506, and processor 504 is connected to the I/O interface via processor interface 508. Memory 520 is connected to processor 502 via a memory interface 522. Memory 525 is connected to processor 504 via a memory interface 527. Graphics interface 530 is connected to I/O interface 510 via a graphics interface 532 and provides a video display output 536 to a video display 534. In a particular embodiment, information handling system 500 includes separate memories that are dedicated to each of processors 502 and 504 via separate memory interfaces. An example of memories 520 and 530 include random access memory (RAM) such as static RAM (SRAM), dynamic RAM (DRAM), non-volatile RAM (NV-RAM), or the like, read only memory (ROM), another type of memory, or a combination thereof.

BIOS/UEFI module 540, disk controller 550, and I/O bridge 570 are connected to I/O interface 510 via an I/O channel 512. An example of I/O channel 512 includes a Peripheral Component Interconnect (PCI) interface, a PCI-Extended (PCI-X) interface, a high-speed PCI-Express (PCIe) interface, another industry standard or proprietary communication interface, or a combination thereof. I/O interface 510 can also include one or more other I/O interfaces, including an Industry Standard Architecture (ISA) interface, a Small Computer Serial Interface (SCSI) interface, an Inter-Integrated Circuit (I²C) interface, a System Packet Interface (SPI), a Universal Serial Bus (USB), another interface, or a combination thereof. BIOS/UEFI module 540 includes BIOS/UEFI code operable to detect resources within information handling system 500, to provide drivers for the resources, initialize the resources, and access the resources. BIOS/UEFI module 540 includes code that operates to detect resources within information handling system 500, to provide drivers for the resources, to initialize the resources, and to access the resources.

Disk controller 550 includes a disk interface 552 that connects the disk controller to HDD 554, to ODD 556, and to disk emulator 560. An example of disk interface 552 includes an Integrated Drive Electronics (IDE) interface, an Advanced Technology Attachment (ATA) such as a parallel ATA (PATA) interface or a serial ATA (SATA) interface, a SCSI interface, a USB interface, a proprietary interface, or a combination thereof. Disk emulator 560 permits SSD 564 to be connected to information handling system 500 via an external interface 562. An example of external interface 562 includes a USB interface, an IEEE 4394 (Firewire) interface, a proprietary interface, or a combination thereof. Alternatively, solid-state drive 564 can be disposed within information handling system 500.

I/O bridge 570 includes a peripheral interface 572 that connects the I/O bridge to add-on resource 574, to TPM 576, and to network interface 580. Peripheral interface 572 can be the same type of interface as I/O channel 512 or can be a different type of interface. As such, I/O bridge 570 extends the capacity of I/O channel 512 when peripheral interface 572 and the I/O channel are of the same type, and the I/O bridge translates information from a format suitable to the I/O channel to a format suitable to the peripheral channel 572 when they are of a different type. Add-on resource 574 can include a data storage system, an additional graphics interface, a network interface card (NIC), a sound/video processing card, another add-on resource, or a combination thereof. Add-on resource 574 can be on a main circuit board, on separate circuit board or add-in card disposed within information handling system 500, a device that is external to the information handling system, or a combination thereof.

Network interface 580 represents a NIC disposed within information handling system 500, on a main circuit board of the information handling system, integrated onto another component such as I/O interface 510, in another suitable location, or a combination thereof. Network interface device 580 includes network channels 582 and 584 that provide interfaces to devices that are external to information handling system 500. In a particular embodiment, network channels 582 and 584 are of a different type than peripheral channel 572 and network interface 580 translates information from a format suitable to the peripheral channel to a format suitable to external devices. An example of network channels 582 and 584 includes InfiniBand channels, Fibre Channel channels, Gigabit Ethernet channels, proprietary channel architectures, or a combination thereof. Network channels 582 and 584 can be connected to external network resources (not illustrated). The network resource can include another information handling system, a data storage system, another network, a grid management system, another suitable resource, or a combination thereof.

Management device 590 represents one or more processing devices, such as a dedicated baseboard management controller (BMC) System-on-a-Chip (SoC) device, one or more associated memory devices, one or more network interface devices, a complex programmable logic device (CPLD), and the like, which operate together to provide the management environment for information handling system 500. In particular, management device 590 is connected to various components of the host environment via various internal communication interfaces, such as a Low Pin Count (LPC) interface, an Inter-Integrated-Circuit (I2C) interface, a PCIe interface, or the like, to provide an out-of-band (OOB) mechanism to retrieve information related to the operation of the host environment, to provide BIOS/UEFI or system firmware updates, to manage non-processing components of information handling system 500, such as system cooling fans and power supplies. Management device 590 can include a network connection to an external management system, and the management device can communicate with the management system to report status information for information handling system 500, to receive BIOS/UEFI or system firmware updates, or to perform other task for managing and controlling the operation of information handling system 500.

Management device 590 can operate off a separate power plane from the components of the host environment so that the management device receives power to manage information handling system 500 when the information handling system is otherwise shut down. An example of management device 590 include a commercially available BMC product or other device that operates in accordance with an Intelligent Platform Management Initiative (IPMI) specification, a Web Services Management (WSMan) interface, a Redfish Application Programming Interface (API), another Distributed Management Task Force (DMTF), or other management standard, and can include an Integrated Dell Remote Access Controller (iDRAC), an Embedded Controller (EC), or the like. Management device 590 may further include associated memory devices, logic devices, security devices, or the like, as needed, or desired.

Although only a few exemplary embodiments have been described in detail herein, those skilled in the art will readily appreciate that many modifications are possible in the exemplary embodiments without materially departing from the novel teachings and advantages of the embodiments of the present disclosure. Accordingly, all such modifications are intended to be included within the scope of the embodiments of the present disclosure as defined in the following claims. In the claims, means-plus-function clauses are intended to cover the structures described herein as performing the recited function and not only structural equivalents, but also equivalent structures.

That which is claimed is:

1. A fluid removal subsystem of an information handling system, the fluid removal subsystem comprising:
an electric self-priming pump, wherein the electric self-priming pump is encased in a housing sized to fit entirely within a chassis of the information handling system and including an intake port and outtake port;
intake tubing connected to the intake port; and
outtake tubing connected to the outtake port,
wherein the electric self-priming pump is configured to draw fluid within the chassis into the intake tubing and discharge the fluid through the outtake tubing to thereby remove at least a portion of the fluid from the chassis.

2. The fluid removal subsystem of claim 1, further comprising:
a fluid sensor operatively coupled with the electric self-priming pump,
wherein the fluid sensor is configured to initiate a priming mode operation of the electric self-priming pump in response to detecting the fluid within the chassis.

3. The fluid removal subsystem of claim 2, wherein the fluid sensor is a capacitive or electro-optic sensor.

4. The fluid removal subsystem of claim 1, wherein a distal end of the intake tubing is configured to fit against a floor of the chassis, and wherein a notch is formed in the distal end of the intake tubing to permit the fluid to be drawn into the intake tubing.

5. The fluid removal subsystem of claim 1, wherein the intake tubing can be positioned within the chassis to capture a flow of fluid naturally occurring within the chassis owing to a slope of a floor of the chassis.

6. The fluid removal subsystem of claim 1, wherein the intake tubing can be positioned to capture fluid flows within one or more fluid channels of the chassis.

7. The fluid removal subsystem of claim 1, wherein the outtake tubing is configured to deliver fluid withdrawn by the electric self-priming pump from the chassis to an external drainage system of a rack assembly.

8. The fluid removal subsystem of claim 1, wherein the electric self-priming pump comprises a piezoelectric self-priming pump.

9. The fluid removal subsystem of claim 1, wherein the electric self-priming pump comprises a brushless direct current (DC) centrifugal pump.

10. A method of excising leaked coolant from an information handling system, the method comprising:
drawing fluid from a chassis of the information handling system into intake tubing in response to suction created by an electric self-priming pump connected with the intake tubing; and
discharging the fluid through outtake tubing connected with the electric self-priming pump to remove at least a portion of the fluid from the chassis of the information handling system,
wherein the electric self-priming pump is encased in a housing sized to fit entirely within the chassis of the information handling system.

11. The method of claim 10, further comprising:
initiating operation of the electric self-priming pump in response to detecting the fluid by a fluid sensor.

12. The method of claim 11, wherein the fluid sensor is a capacitive or electro-optic sensor.

13. The method of claim 10, wherein a distal end of the intake tubing is configured to fit against a floor of the chassis, and wherein a notch is formed in the distal end of the intake tubing to permit the fluid to be drawn into the intake tubing.

14. The method of claim 10, wherein the intake tubing can be positioned within the chassis to capture a flow of fluid naturally occurring within the chassis owing to a slope of a floor of the chassis.

15. The method of claim 10, wherein the intake tubing can be positioned to capture fluid flows within one or more fluid channels of the chassis.

16. The method of claim 10, wherein the outtake tubing is configured to deliver fluid withdrawn by the electric self-priming pump from the chassis to an external drainage system of a rack assembly.

17. The method of claim 10, wherein the electric self-priming pump comprises a piezoelectric self-priming pump.

18. The method of claim 10, wherein the electric self-priming pump comprises a brushless direct current (DC) centrifugal pump.

19. A liquid-cooled information handling system, comprising:
a chassis;
one or more processors; and
a fluid removal subsystem, the fluid removal subsystem including:
an electric self-priming pump located near the processors in the chassis, wherein the electric self-priming pump is encased in a housing sized to fit entirely within the chassis of the liquid-cooled information handling system and including an intake port and outtake port;
intake tubing connected with the electric self-priming pump via the intake port; and
outtake tubing connected with the electric self-priming pump via the outtake port,
wherein the electric self-priming pump is configured to draw fluid within the chassis into the intake tubing and discharge the fluid through the outtake tubing to remove at least a portion of the fluid from the chassis.

20. The liquid-cooled information handling system of claim 19, wherein the fluid removal subsystem further includes:
a fluid sensor operatively coupled with the electric self-priming pump,
wherein the fluid sensor is configured to initiate operation of the electric self-priming pump in response to detecting the fluid within the chassis.
